(19) United States
(12) Patent Application Publication
(10) Pub. No.: US 2014/0178517 A1
(43) Pub. Date: Jun. 26, 2014

(54) DEVICE FOR MANUFACTURING PHOSPHOR FILM FOR USE IN LED

(71) Applicant: HON HAI PRECISION INDUSTRY CO., LTD., New Taipei (TW)

(72) Inventor: CHEN-HAN LIN, New Taipei (TW)

(73) Assignee: HON HAI PRECISION INDUSTRY CO., LTD., New Taipei (TW)

(21) Appl. No.: 14/019,559

(22) Filed: Sep. 6, 2013

(30) Foreign Application Priority Data
Dec. 26, 2012 (TW) 101150046

(51) Int. Cl. H01L 33/44

(52) U.S. Cl. CPC H01L 33/44
USPC 425/174.4; 425/224

(57) ABSTRACT

A device for manufacturing a phosphor film, includes a container for receiving and mixing a raw material of the phosphor film which includes phosphor powders and glue; a conveyor belt for transporting the mixed raw material from the container, the conveyor belt comprising two horizontal portions and an arc portion arranged between the two horizontal portions, the arc portion defining a recess downwardly; and a roller located above the arc portion of the conveyor belt and partly received in the recess, a distance being kept between the arc portion and the roller, the raw material being pressed by the roller during transportation by the conveyor belt to form the phosphor film. A curing device radiates ultraviolet to the mixed material on the arc portion of the conveyor belt to cure the glue thereof.

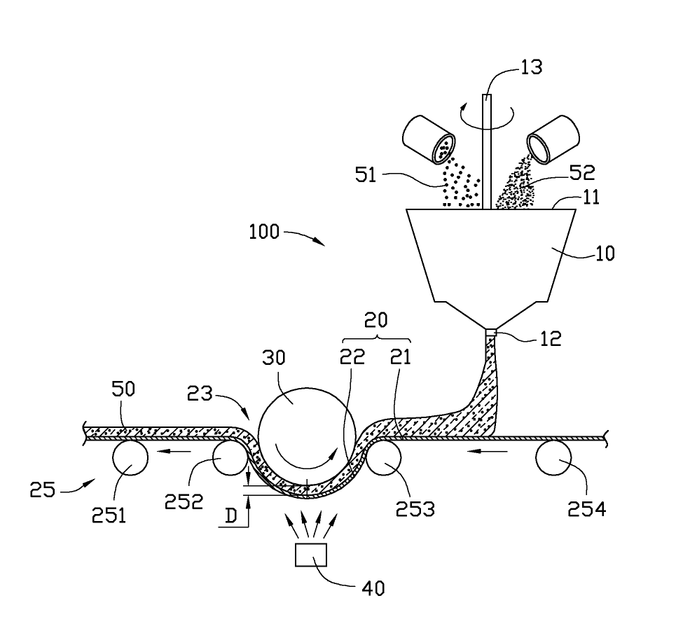

### BACKGROUND

1. Technical Field

The disclosure relates to a device for manufacturing a phosphor film, wherein the phosphor film is used to be located over a light diffusion plate for evenly converting light from an LED (light emitting diode) through the diffusion plate to light having a desired color different from the original color.

2. Description of Related Art

Light emitting diodes' (LEDs) many advantages, such as high luminosity, low operational voltage, low power consumption, compatibility with integrated circuits, easy driving, long term reliability, and environmental friendliness have promoted their wide use as a lighting source.

A typical LED usually uses a blue LED chip as an initial light source to produce a white light. The blue light emitted from the blue LED chip strikes yellow phosphor powders dispersed in an encapsulation enclosing the blue LED chip to generate a yellow secondary color light. The combination of the yellow secondary color light and residual blue light produces a white light. However, the density of the phosphor powders in the encapsulation is not evenly distributed. Furthermore, the encapsulation has an uneven thickness. As a result, the white light may have a yellow halo and does not provide even illumination.

Therefore, what is needed is a device for manufacturing a phosphor film which can overcome the described limitations.

### BRIEF DESCRIPTION OF THE DRAWINGS

Many aspects of the disclosure can be better understood with reference to the following drawing. The components in the drawing are not necessarily drawn to scale, the emphasis instead being placed upon clearly illustrating the principles of the present light emitting diode package for microminiaturization. Moreover, in the drawing, like reference numerals designate corresponding parts throughout the whole view.

The only drawing is a schematic view of a device for manufacturing a phosphor film according to an exemplary embodiment of the present disclosure.

### DETAILED DESCRIPTION OF EMBODIMENTS

Referring to the only drawing, a device 100 for manufacturing a phosphor film 50 in accordance with an exemplary embodiment of the present disclosure is illustrated. The phosphor film 50 is used to be located over a diffusion plate which is located over an LED for converting light generated by the LED to light have a desired color. Generally the light from the LED has a blue color. The blue light, after conversion by the phosphor film, becomes white light. The device 100 for manufacturing the phosphor film 50 includes a container 10, a conveyor consisting of a conveyor belt 20 and driving wheels 251, 252, 253, 254, a roller 30 and a curing unit 40.

The container 10 receives phosphor powders 51 and glue 52. A bottom portion of the container 10 is cone-shaped. The container 10 includes an inlet opening 11 at a top portion thereof and an outlet opening 12 at the bottom portion thereof. An agitator 13 is arranged in the container 10 and extends outwardly from the inlet opening 11. The raw material including the phosphor powders 51 and the glue 52 is put into the container 10 via the inlet opening 11 and mixed together evenly by the agitator 13, and then flows to the conveyor belt 20 via the outlet opening 12. In the present embodiment, the glue 52 is UV curing glue, and can be solidified by ultraviolet radiation.

The conveyor belt 20 is arranged at a bottom of the container 10, and the mixed phosphor powders 51 and glue 52 flow from the outlet opening 12 and drop to the conveyor belt 20. The conveyor belt 20 includes a first and a second horizontal portion 21 and an arc portion 22. The arc portion 22 is arranged between the first and second horizontal portions 21 and defines a semicircular recess 23 downwardly. In the present embodiment, a cross section of the arc portion 22 is a circular arc with a first center of a circle. The conveyor belt 20 is driven to move by the plurality of driving wheels 25. In the present embodiment, a first, a second, a third and a fourth wheel 251, 252, 253, 254 are arranged at a bottom of the conveyor belt 20 in sequence. The first horizontal portion 21 near the container 10 is located above the third wheel 253 and the fourth wheel 254, the second horizontal portion 21 is located above the first wheel 251 and the second wheel 252, and the arc portion 22 is located between the second wheel 252 and the third wheel 253.

The roller 30 is located above the arc portion 22 of the conveyor belt 20 and partially received in the recess 23. A distance D is kept between the arc portion 22 and the roller 30, which is equal to a desired thickness of the phosphor film 50. An exterior surface of the roller 30 is a circle with a second center of a circle. In the present embodiment, the second center of a circle is coincidental with the first center of a circle; therefore, the distance D is a constant. The arc portion 22 of the conveyor belt 20 moves along a circumferential direction of the circle defining the first center clockwise from a right side to a left side, and a rotating direction of the roller 30 is opposite to that the moving direction of the arc portion 22 (i.e., the roller 30 rotating anticlockwise); therefore, the relative speed between the roller 30 and the arc portion 22 is high, and the phosphor powders 51 and glue 52 can be mixed more evenly and quickly. The mixed phosphor powders 51 and glue 52 dropped to the first horizontal portion 21 of the conveyor belt 20 is conveyed to the arc portion 22 via the conveyor belt 20, and then pressed by the roller 30 to form a gelatinize phosphor film 50 with a desired thickness.

The curing unit 40 is used to make the gelatinize phosphor film 50 to a solid phosphor film 50. The curing unit 40 can be a roaster or a radiator. In the present embodiment, the curing unit 40 is an ultraviolet radiator and located below the arc portion 22 of the conveyor belt 20.

The raw material of phosphor powders 51 and glue 52 is put into the container 10 via the inlet opening 11 and mixed together evenly by the stick 13, and then flows to the first horizontal portion 21 of the conveyor belt 20 via the outlet opening 12. The mixed phosphor powders 51 and glue 52 are pressed by the roller 30 meanwhile the glue 52 is solidified by the curing unit 40 which radiates the glue 52 with UV to form the phosphor film 50. Thus, the phosphor film 50 has evenly distributed phosphor powders 51 therein. Furthermore, the rotating direction of the roller 30 is opposite to that the moving direction of the arc portion 22; therefore, the relative speed between the roller 30 and the arc portion 22 is high, and the phosphor film 50 can be manufactured quickly.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A device for manufacturing a phosphor film configured for use to be located over a diffusion plate to convert light from an LED through the diffusion plate to light having a different color, the device comprising:
a container for receiving and mixing a raw material of the phosphor film which comprises glue and phosphor powders;
a conveyor belt for transporting the mixed raw material from the container, the conveyor belt comprising two horizontal portions and an arc portion arranged between the two horizontal portions, the arc portion defining a recess downwardly; and
a roller located above the arc portion of the conveyor belt and partly received in the recess, a distance being kept between the arc portion and the roller, the mixed raw material being pressed by the roller during transportation by the conveyor belt to form the phosphor film.

2. The device of claim 1, wherein a cross section of the arc portion is a circular arc with a first center of a circle.

3. The device of claim 2, wherein an exterior surface of the roller is a circle with a second center of a circle which is coincidental with the first center of a circle.

4. The device of claim 1, wherein the container comprises an inlet opening at a top portion thereof and an outlet opening at the bottom portion thereof.

5. The device of claim 4, wherein the container further comprises an agitator arranged in the container and extending outwardly from the inlet opening for mixing the law material.

6. The device of claim 1, further comprising a plurality of wheels, the conveyor belt being moved by the wheels.

7. The device of claim 6, wherein the wheels comprises a first, a second, a third and a fourth wheel arranged on a bottom of the conveyor belt in sequence.

8. The device of claim 7, wherein the arc portion is located between the second wheel and the third wheel.

9. The device of claim 7, wherein one of the horizontal portions is located above the first and second wheels, and the other horizontal portion is located above the third and fourth wheels.

10. The device of claim 1, further comprising a curing unit located below the arc portion, the curing unit solidifying the glue of the mixed raw material on the arc portion of the conveyor belt.

11. The device of claim 1, wherein the curing unit is an ultraviolet radiator.

12. The device of claim 1, wherein the distance between the arc portion and the roller is a constant.

13. A device for manufacturing a phosphor film for use to convert light from an LED to light having a different color, comprising:
a container comprising an inlet opening at a top portion thereof and an outlet opening at the bottom portion thereof;
a conveyor belt comprising two horizontal portions and an arc portion arranged between the two horizontal portions, the arc portion defining a recess downwardly; and
a roller located above the arc portion of the conveyor belt and partly received in the recess, a distance being kept between the arc portion and the roller;
wherein a raw material which comprises glue and phosphor powders is mixed in the container, and conveyed to the arc portion of the conveyor, belt and pressed by the roller to form the phosphor film.

14. The device of claim 13, further comprising a curing unit which radiates ultraviolet to the mixed raw material on the arc portion of the conveyor belt to cure the glue.

15. The device of claim 13, wherein a rotating direction of the roller is opposite to a moving direction of the arc portion of the conveyor belt.
